(19) United States
(12) Patent Application Publication
(10) Pub. No.: US 2017/0123008 A1
(43) Pub. Date: May 4, 2017

(54) DEVICE AND METHOD FOR DETECTING TRANSIENT ELECTRICAL SHORT CIRCUITS IN A BATTERY CELL OR PACK

(71) Applicant: Boston-Power, Inc., Westborough, MA (US)

(72) Inventors: Rui E. Frias, East Freetown, MA (US); Nino M. Paldan, Westborough, MA (US)

(21) Appl. No.: 14/932,039

(22) Filed: Nov. 4, 2015

(51) Int. Cl. G01R 31/36; H02H 7/18; H02H 9/00

(52) U.S. Cl. CPC G01R 31/362; H02H 9/005; H02H 7/18

(57) ABSTRACT

A battery system employs a device for indicating micro-shorts occurring within one or more battery cells. The device detects whether a given battery cell or group of cells exhibits a transient electrical short circuit, such as a micro-short circuit, which can indicate a defect within the battery cell. The device receives a signal indicating the voltage of the given battery cell or group of cells, and compares the signal against a delayed version of the signal to detect the transient electrical short circuit. When a transient electrical short circuit is detected, the device outputs a corresponding fault signal to a battery management system (BMS), configured to monitor the battery cell. The BMS may then take further remedial action to prevent damage to the battery system.

### BACKGROUND

Batteries used in single or battery pack applications are susceptible to internal defects that can cause an internal short circuit. A single individual cell failure can propagate to others and cause battery pack thermal runaway. Moreover, it is desirable to avoid operation of most battery cells above 60° C. Operation at temperatures above 60° C. may substantially limit a battery cell's cycle life. Lithium ion (LiIon) battery cells, for example, can enter a thermal runaway condition at elevated temperatures (typically above 75° C.), leading to catastrophic failure and creating a safety hazard.

Transient internal short-circuits, also referred to as “soft-shorts” or “micro-shorts,” can result from small, localized contacts between the electrodes of a battery cell. During the charging and taper of a battery, micro-shorts can indicate that there is an internal defect. Over time, these micro-shorts may transition to a “hard” short across the battery cell, which can cause thermal runaway or other problems. Although a thermistor device within a battery pack will provide a means of temperature fault detection, such devices cannot detect an internal cell defect that may later cause such a fault.

A typical battery pack, such as a battery pack employed in automotive applications (e.g., electric vehicles), includes a battery management system (BMS), which interfaces with a battery module to monitor the state of component battery cells, including temperature and cell voltages of such battery cells. A BMS can monitor the voltages of the individual battery cells. Typically, however, battery management systems sample voltage data at a given resolution (e.g., 20 milliseconds (ms) or greater) that is insufficient to detect a micro-short. Providing a BMS with a smaller sample size sufficient to detect micro-shorts in the cell voltage generally is very expensive. Another alternative would be to employ a BMS that can also monitor the temperature of a battery module however, such monitoring typically detects thermal runaway only after it has begun, potentially resulting in damage to the battery system

Therefore, there is a need for a device and method for battery cell transient electrical short circuit detection that can indicate a defect at a specific battery cell that overcomes or minimizes these limitations.

### SUMMARY

The present invention is generally directed to a device and method for indicating micro-shorts of one or more battery cells in a battery system.

In one embodiment, the present invention includes a BMS, a comparator gate, and a time delay circuit. The BMS is in electrical communication with terminals configured for connection with a battery, including an input voltage connection that is in electrical communication with a positive terminal of the battery, and including an output voltage connection that is in electrical communication with a negative terminal of the battery. The comparator gate is connected in parallel with electrical communication between the positive terminal of the battery and the input voltage connection, the comparator gate including a first input and a second input that are in electrical communication with the positive terminal of the battery, and an output in electrical communication with the battery management system. The time delay circuit is between the positive terminal of the battery and the second input of the comparator gate, whereby communication of a micro short circuit in the battery is delayed by the time delay circuit, thereby causing the comparator gate to communicate, via the output, the transient short circuit to the battery management system over two distinct intervals that, in aggregate, are identified by the battery management system as a transient short circuit in the battery.

In further embodiments, the comparator gate can be a NAND gate. Alternatively, the comparator gate can be an AND gate, or may be a voltage comparator or other circuitry configured to compare the voltage at the positive battery terminal and the output of the time delay circuit.

In another embodiment, the invention is a method for detecting a transient electrical short circuit that includes transmitting a first signal in parallel from a battery cell to a comparator gate and to a time delay circuit. The first signal is delayed at the time delay circuit to thereby form a second signal. The second signal is transmitted in parallel with the first signal to the comparator gate. The first and second signals at the comparator gate are compared, thereby generating a third signal wherein a transient drop in voltage in the first and second signals indicative of a transient short circuit in the battery cell is prolonged. The third signal is transmitted to the battery management system, whereby the prolonged transient drop in voltage is detected by the battery management system, thereby detecting the transient electrical short circuit in the battery.

Embodiments of the invention provide a number of advantages over existing techniques for monitoring micro-short circuits in a battery cell. For example, such embodiments can utilize existing monitoring channels and employ one or more detectors in connection with those channels at the battery module to provide for monitoring one or multiple individual cells for micro-shorts within a battery block. Thus, if an excessive micro-short is detected, a corresponding fault can be reported to the BMS for further remedial action. As a result, example embodiments can provide per-cell micro-short circuit monitoring, detection and reporting to the BMS using low-cost circuitry, without requiring substantial additional circuitry at the BMS.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a block diagram of a battery system implementing a detector in one embodiment of the invention.

FIG. 2 is a timing diagram illustrating micro-shorts exhibited by a battery cell in the prior art.

FIG. 3 is a block diagram of a detector device in another embodiment of the invention.

FIG. 4 is a timing diagram illustrating detection of micro-shorts in the embodiment of the invention of FIG. 3.

FIG. 5 is a block diagram of a detector device in a further embodiment of the invention.

FIG. 6 is a timing diagram illustrating detection of micro-shorts in the embodiment of the invention of FIG. 5.

FIG. 7 is a block diagram of a battery system implementing a plurality of detectors in still another embodiment of the invention.

FIG. 8 is a block diagram of a battery system implementing a detector in yet another embodiment of the invention.

FIG. 9 is a block diagram of a detector device in a further embodiment of the invention.

FIG. 10 is a timing diagram illustrating detection of micro-shorts in the embodiment of the invention of FIG. 9.

### DETAILED DESCRIPTION

A description of example embodiments of the invention follows.

The invention generally is directed to a device and method for detecting a transient electrical short circuit, such as a micro-short circuit, in a battery cell. In one embodiment, the device of the invention indicates a micro-short circuit fault at one or more battery cells. The device detects whether a given battery cell or group of cells is exhibiting a transient electrical short circuit, such as a micro-short circuit (also referred to as “micro-short”). In response, the device outputs a corresponding fault signal to a battery management system (BMS) interfacing with the battery cell. A “battery management system,” as defined herein, is an electrical system that at least monitors rechargeable battery cells. In some embodiments, a BMS can manage rechargeable cells, such as by controlling charging and discharging of the cells, and by protecting them from operating under unsafe conditions.

The BMS, configured to monitor the voltage of the battery cell, detects the fault signal as an indication that a micro-short has occurred within the battery cell. The device can be connected to existing channels for monitoring the cell voltage, and detects whether a given battery cell or group of cells exhibits a micro-short, thereby indicating a defect within the battery cell. When a transient electrical short circuit, such as a micro-short, is detected, the device outputs a corresponding fault signal to a BMS, configured to monitor the battery cell. The BMS can then take further remedial action to prevent damage to the battery system. As a result, a battery system in one embodiment provides low-cost micro-short detection of individual battery cells and reporting an indication of the same to a BMS.

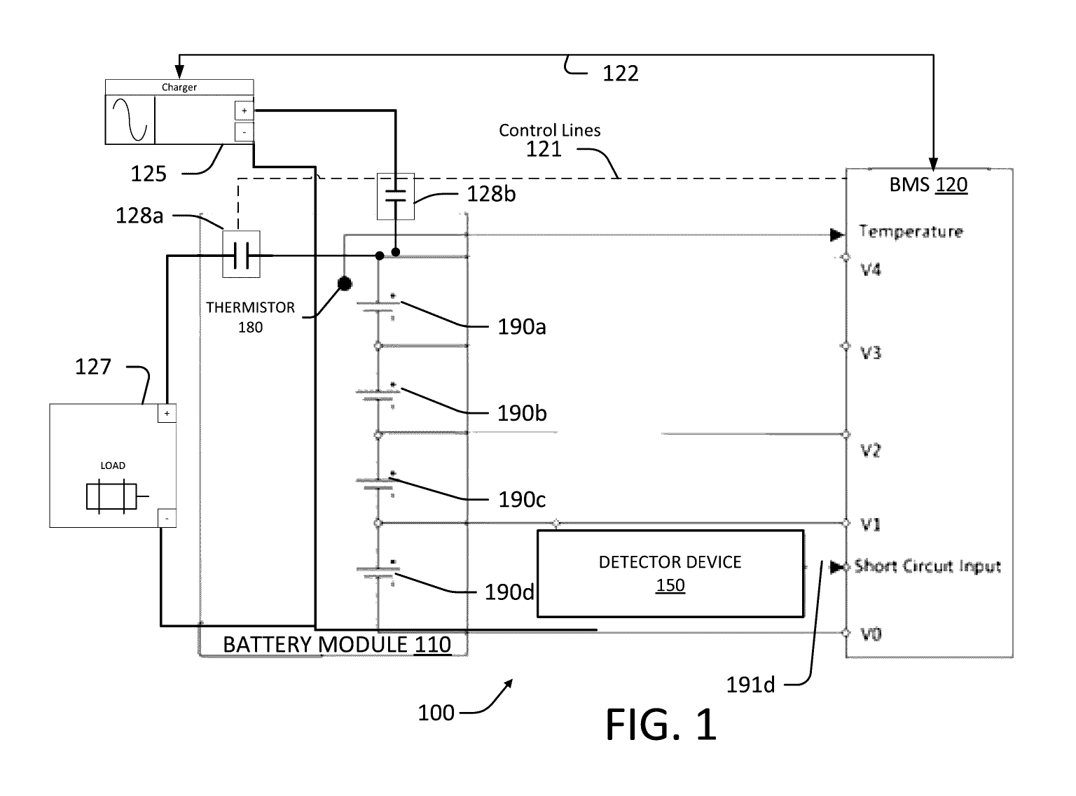

FIG. 1 is a block diagram of battery system 100 in which embodiments of the present invention may be implemented. Battery system 100 includes battery module 110 in connection with BMS 120. Battery module 110 includes plurality of battery cells 190a-d connected in series and configured to provide power to a load (not shown) via connection across the terminals of one or more of cells 190a-d. In further embodiments, battery module 110 can include a greater or lesser number of cells, which can be connected in series, in parallel, or in a combination thereof. For example, battery module 110 can be implemented as a battery pack for an electric vehicle, and include a number of cells configured to provide the voltage and capacity required to propel an automobile.

BMS 120 operates to manage battery module 110, as well as any other batteries (not shown) to which it may be connected. In managing battery module 110, BMS 120 can provide one or more of a number of functions, such as monitoring its state, protecting battery module 110 from operating parameters (e.g., temperature, voltage) determined to be unsafe, selectively enabling and disabling the battery cells, calculating and reporting secondary data, and balancing battery module 110. In order to provide such functions, BMS 120 may interface with battery module 110 via a number of communication channels. In particular, BMS 120 receives voltage inputs V0-V4, which connect to terminals across each of cells 190a-d. Inputs V0-V4 enable BMS 120 to monitor the voltage of each cell 190a-d individually. BMS 120 also receives a measurement of temperature at the battery module 110 via a separate channel connected to thermal resistor (“thermistor”) 180 at the battery module. Thermistor 180 can be, for example, a PTC device, and can be located proximate to a single cell (e.g., cell 190a), a group of cells, or a separate region of battery module 110. BMS 120 can also interface with battery module 110 via additional channels (not shown) to provide additional monitoring and control of battery module 110.

Under normal operation, battery module 110 selectively delivers power to load 127 (e.g., an electric motor) by connecting cells 190a-d across the terminals of load 127. To control discharge of battery module 110 to power load 127, BMS 120 selectively enables the circuit via load contactor 128a connected to BMS 120 via control line 121. Battery module 110 is also selectively charged by battery charger 125 by connecting cells 190a-d across the terminals of battery charger 125. To control charging of battery module 110, BMS 120 communicates with charger 125 via communications channel 122 to control charger 125 and receive an indication of the state of the charge, and selectively enables load contactor 128b via control line 121. Further, during a temperature fault, BMS 120 can halt charging and/or discharging by disabling one or both of load contactors 128a-b.

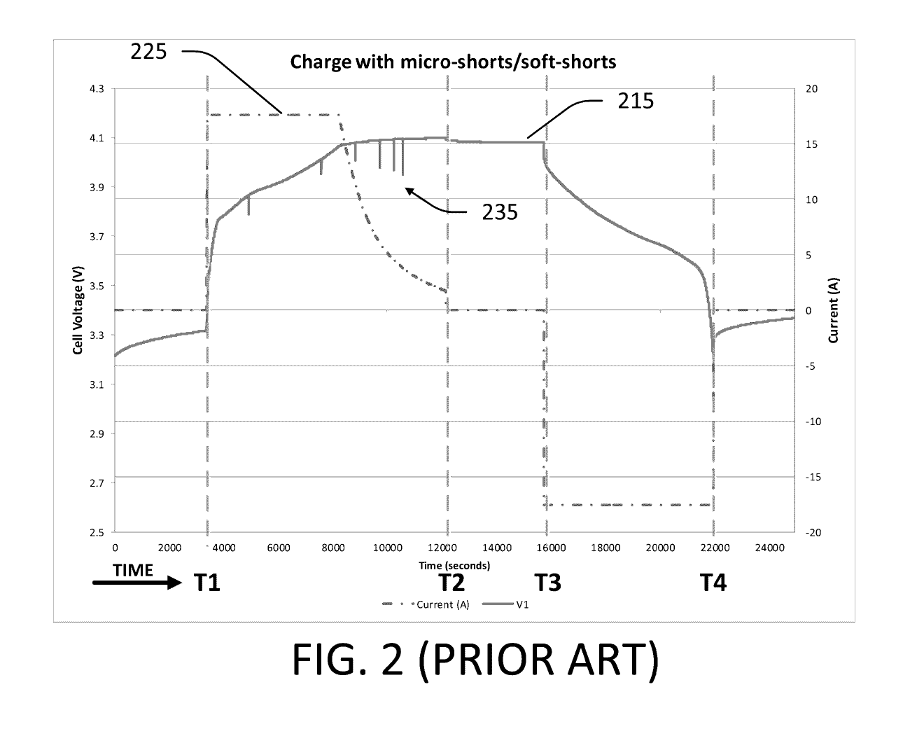

FIG. 2 is a timing diagram illustrating prior art voltage 215 and current 225 of a battery cell during a charge of the cell, followed by a discharge. With reference to FIG. 1, for example, each of cells 190a-d may exhibit voltage and current characteristics comparable this timing diagram during respective charging and discharging modes of operation. In particular, at time T1, a charge of a battery cell is initiated, where current begins flowing to the battery cell and the cell voltage begins to rise. Upon approaching a full charge of the battery cell (indicated by the cell tapering to a threshold voltage and a declining charging current to the cell), the charge is terminated at time T2. Later, discharge of the battery cell occurs between times T3 and T4, indicated by negative current and declining voltage across the battery cell.

Turning again to FIG. 1, each of battery cells 190a-d may exhibit micro-shorts during a charge. For a given cell (e.g., cell 190d), such micro-shorts are illustrated in FIG. 2 as transient negative spikes 235 in the cell voltage between times T1 and T2. Such micro-shorts, as described above, can indicate an internal defect at one or more of the battery cells 190a-d. Over time, such defects can cause an individual cell failure that may propagate to other battery cells, causing thermal runaway of battery module 110 or other adverse effects. Because BMS 120 is configured to receive voltage inputs V0-V4 across each of individual cells 190a-d, BMS 120 may receive the voltage of each cell 190a-d over time, including the transient shorts. However, due to the short duration of the micro-shorts (e.g., less than 20 milliseconds (ms)), being smaller than the data sample rate (e.g., 20 ms or greater) of a typical BMS, BMS 120 may fail to detect micro-shorts via voltage inputs V0-V4.

Embodiments of the invention may employ detector device 150 to provide for monitoring and detection of transient electrical short circuits at one or multiple individual cells 190a-d within battery module 110. Device 150 can be connected to one or more existing channels for monitoring cell voltage (e.g., channel V1). If a micro-short is detected, a corresponding fault can be reported to BMS 120 via a corresponding input (e.g., a “short circuit input”). As a result, detector device 150 can provide per-cell micro-short monitoring and detection to BMS 120. As shown in FIG. 1, detector device 150 is configured to monitor battery cell 190d for micro-shorts. In alternative embodiments, detector device 150 can be configured to monitor one or more of battery cells 190a-d.

Upon receiving an indication of a micro-short, BMS 120 can, for example, take appropriate action to ensure the continued safe operation of battery system 100. In one embodiment, if the micro-shorts indicate that a single battery cell (e.g., cell 190d) is defective, BMS 120 can issue an alert to a vehicle control unit (VCU, not shown) or a diagnostic system to indicate that the defective cell must be replaced. If the defective cell is not replaced and the micro-shorts continue, then BMS 120 may take further action. For example, BMS 120 may disable charging or discharging of battery module 110, modify operating parameters of battery module 110, or issue an alert for further intervention.

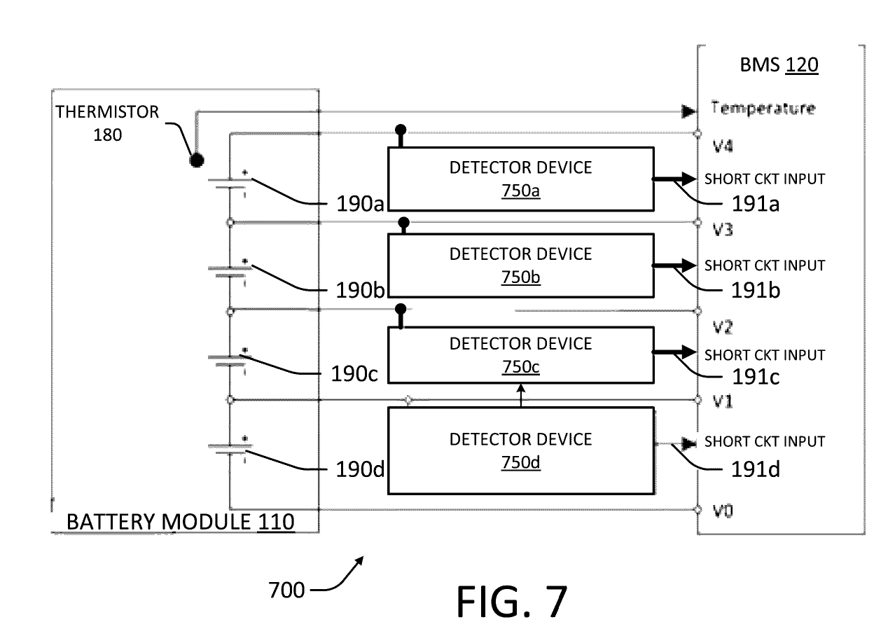

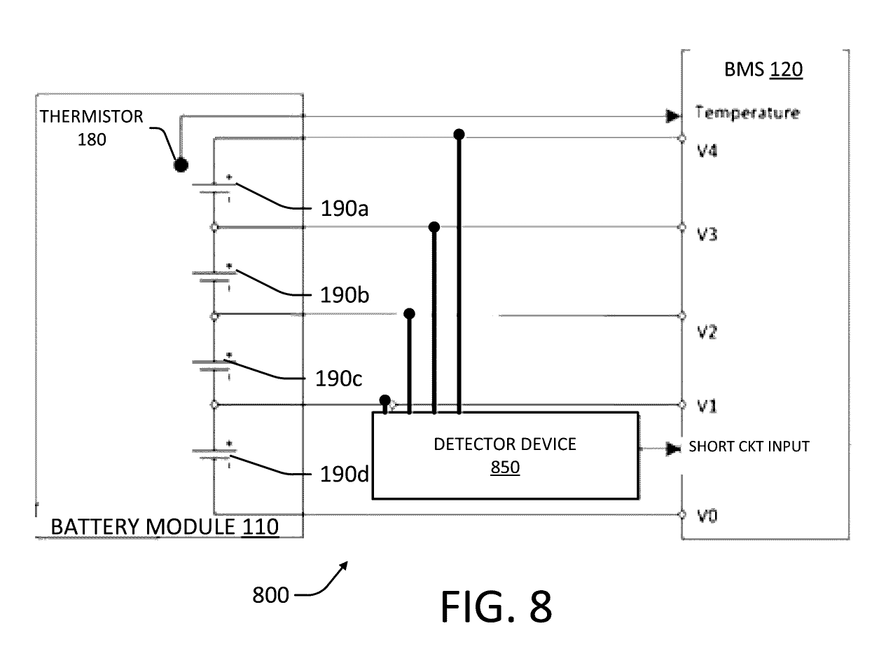

As shown in FIG. 1, detector device 150 is implemented to receive the voltage at single battery cell 190d, thereby detecting micro-shorts exhibited by single cell 190d. In a further embodiment, a plurality of devices such as the detector device 150 can be implemented in the battery system 110, where each device is configured to detect a short at a respective one of battery cells 190a-d. An example of such a configuration is described in further detail below with reference to FIG. 7. In a still further embodiment, detector device 150 can be configured to receive the voltages at two or more of battery cells 190a-d (e.g., at voltage channels V1-V4), thereby detecting micro-shorts exhibited by a plurality of battery cells. An example of such a configuration is described in further detail below with reference to FIG. 8.

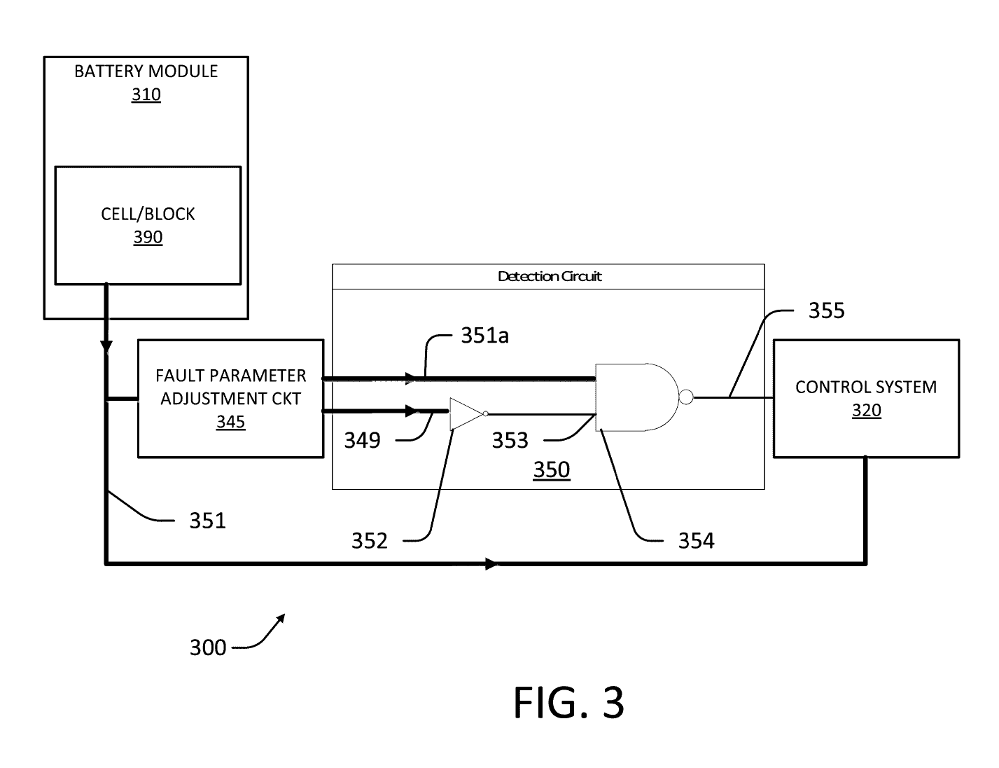

FIG. 3 is a block diagram of battery system 300 including detector device 350 in one embodiment of this invention. Detector device 350 may be implemented in battery system 100 (e.g., as detector device 150) described above with reference to FIG. 1, and may incorporate features of detector device 150 described above. In particular, battery module 310 sends signal 351 to detector circuit 350 indicating the voltage of battery cell 390 (or, alternatively, a plurality of battery cells or a battery module). Battery module 310 corresponds to one or more of battery cells 190a-d of FIG. 1. Device 350 also outputs signal 355 to control system 320 (e.g., a battery management system such as BMS 120, described above). Further, fault parameter adjustment circuit 345 is an optional component between the cell 390 and the detector device 350. Circuit 345 may include fault parameter adjustment circuit 345, which operates to adjust the voltage range of signal 351 received by device 350. By adjusting the voltage range, circuit 345 controls the amplitude of transient electrical short circuit signals received by detector device 350. Alternatively, circuit 345 may be incorporated into detector device 350.

Detector device 350 includes delay circuit 352 (e.g., one or more inverter gates) and NAND gate 354 input 349, which is employed as a comparator gate. Both delay circuit 352 and first input 351a to NAND gate 354 receive the same or comparable signals from circuit 345 corresponding to the voltage of battery cell 390. Delay circuit 352 outputs a delayed version of signal 349 as second input of NAND gate 354. During charge or discharge of battery cell 390, absent the occurrence of micro-shorts, NAND gate 354 outputs a steady-state signal to control system 320. Conversely, in the event of a micro-short, first input 351a of NAND gate 354 receives a voltage signal that includes a negative spike corresponding to the micro-short, and a second input 353 of NAND gate 354 receives (from delay circuit 352) a delayed version of the negative spike corresponding to the micro-short. The delay in the spike received at first input 351A and second input 353 of NAND gate 354 creates a prolonged signal that causes NAND gate 354 to change its output state (e.g., from “high” to “low,” or from “low” to “high”). This state change is, in turn, detected by control system 320, indicating the occurrence of a micro-short.

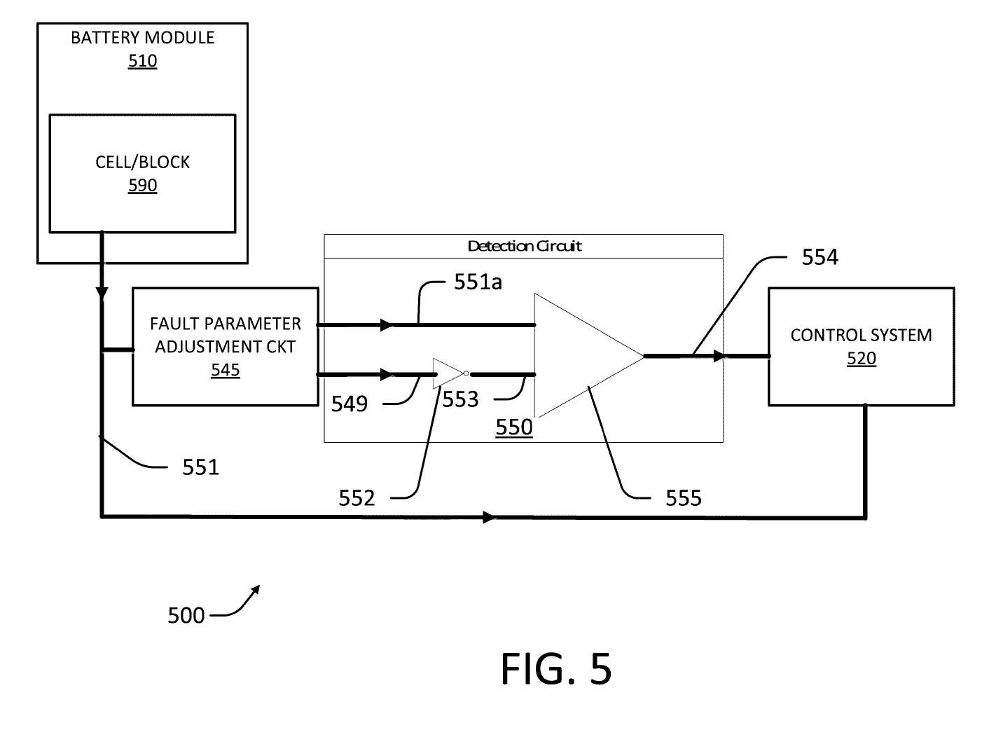

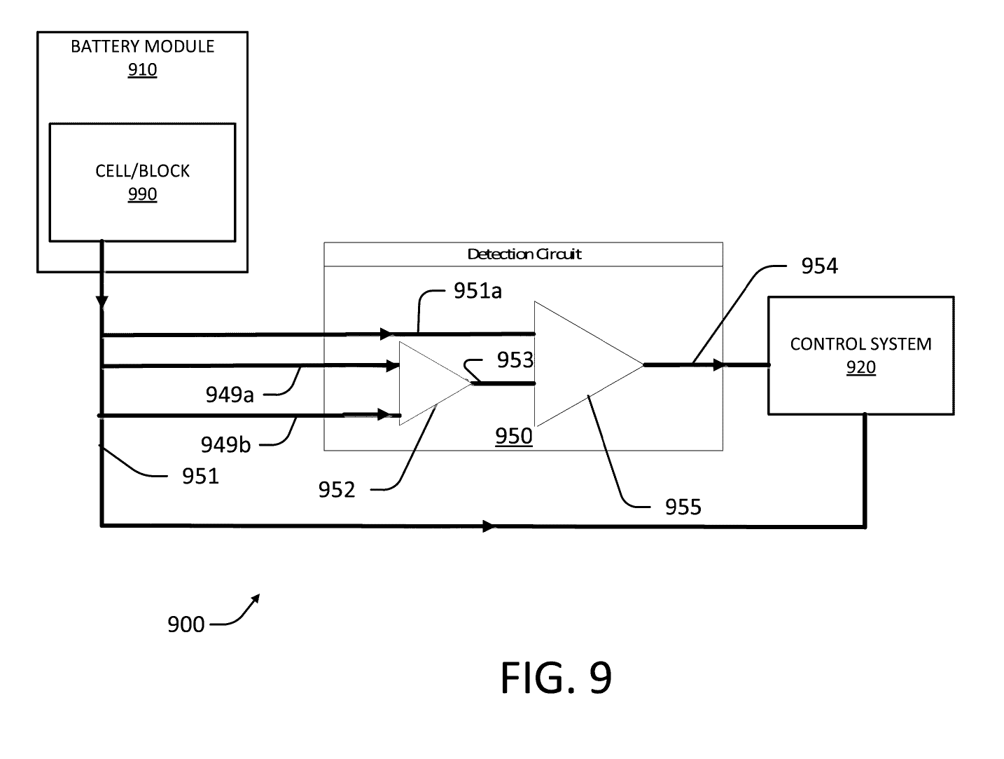

Delay circuit 352 and NAND gate 354 may be configured, based on the characteristics of the micro-shorts, to provide reliable detection of the micro-shorts. For example, delay circuit 352 can provide a given delay of 1 mS, to thereby generate a prolonged signal of 1 mS, and NAND gate 354 can be configured to change state only if the negative voltage spike detected at input 351 first and second input 353 is greater than 100 mV. Further, one of ordinary skill in the art would understand that various circuit components can be implemented in place of delay circuit 352, NAND gate 354, or both, to provide a comparable or suitable output indicating a micro-short. For example, an AND gate or voltage comparator can be implemented in place of NAND gate 354, as described below with reference to FIG. 5. In another alternative, an inverter circuit may be employed, for example, in place of delay circuit 352, as described below with reference to FIG. 9.

Referring to FIG. 3, detector 350 receives a signal corresponding to the voltage at battery cell 390, determines whether this voltage exhibits a transient electrical short circuit, such as a micro-short circuit, and, if so, communicates this information via output signal 355 to control system 320.

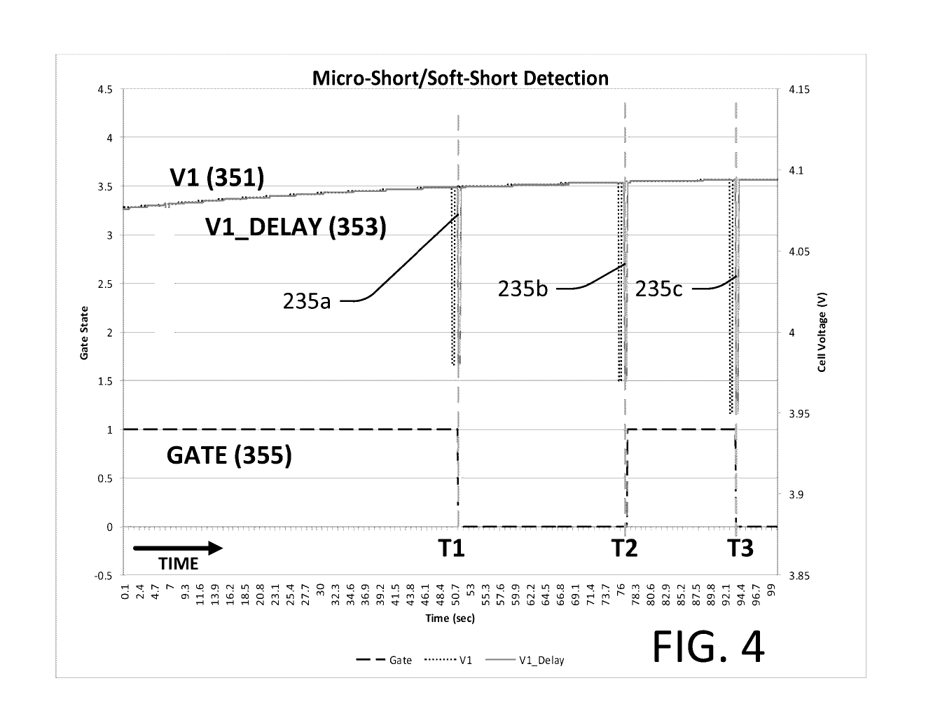

FIG. 4 is a timing diagram illustrating detection of micro-shorts by a detector device in one embodiment of the invention. With reference to FIG. 3, FIG. 4 illustrates signals corresponding to first input 351 of NAND gate 354 (V1), a delayed signal at second input 353 of the NAND gate 354 (V1_Delay), and output 355 of NAND gate (“Gate”) 354, which corresponds to the output of detector 350. At time T1, first micro-short 235a occurs, and is indicated by the negative spike of both V1 and V1_Delay, respectively. Due to the time delay between these signals, the negative spikes occur at different intervals (e.g., 1 mS apart), causing NAND gate 354 to change the state of Gate signal 355 from “high” to “low.” At T2, second micro-short 235b occurs, causing Gate signal 355 to revert from “low” to “high.” Finally, at T3, third micro-short 235d causes yet another state change in Gate signal 355.

In contrast to micro-shorts 235a-c, which exhibit a time period of approximately 10 ms, the state change of Gate signal 355 exhibits a time period equal to the time between successive micro-shorts (e.g., T2-T1, T3-T2), which is greater than the time period of micro-shorts 235a-c. While control system 320 may require additional circuitry to detect the occurrence of micro-shorts 235a-c based solely on signals V1 or V1_Delay, control system 320 can read the state change of Gate signal 355 to detect micro-shorts 235a-c, and without requiring such circuitry (e.g., a high-frequency digital signal detector configured to sample the voltage data at a resolution under 20 milliseconds).

FIG. 5 is a block diagram of battery system 500 including detector device 550 in another embodiment of the invention. Detector device 550 can be implemented in battery system 100 described above with reference to FIG. 1, corresponding to detector device 150, which is also described above. In particular, battery module 510 sends signal 551 to detector 550 indicating the voltage of battery cell 590 (or, alternatively, a plurality of battery cells or a battery module), which corresponds to battery cells 190a-d of FIG. 1. Device 550 also outputs a signal 554 to control system 520, corresponding to BMS 120 of FIG. 1. Further, fault parameter adjustment circuit 545 is an optional component between cell 590 and detector device 550. Circuit 545 includes a voltage divider, which operates to adjust the voltage range of the signal received by detector device 550. By adjusting the voltage range, circuit 545 controls the amplitude of transient electrical short circuits, such as micro-short circuits, as received by detector device 550. Alternatively, circuit 545 can be incorporated into detector device 550.

Detector device 550 corresponds to detector device 350 of FIG. 3, and can incorporate features of device 350 as described above. For example, as shown, device 550 includes delay circuit 552 (e.g., one or more inverter gates). However, in place of a NAND gate, device 550 includes voltage comparator 555. Both input 549 of delay circuit 552 and first input 551A of comparator 555 can receive the same or a comparable signal from circuit 545 corresponding to the voltage of battery cell 590. Delay circuit 552 outputs a delayed version of this signal as second input 553 of comparator 555. During a charge or discharge of battery cell 590, absent the occurrence of a transient electrical short circuit, such as a micro-short, comparator 555 outputs a steady-state signal to control system 520. Conversely, in the event of a micro-short, first input 551a of comparator 555 receives the voltage signal indicating a negative spike corresponding to the micro-short, and second input 553 to comparator 555 is (from delay circuit 552) a delayed version of the negative spike corresponding to the micro-short. The delay in the spike received at first input 551a and second input 553 of comparator 555 causes comparator 555 to output a pulse. This pulse may, in turn, be detected by control system 520, indicating the occurrence of a transient electrical short circuit, such as a micro-short.

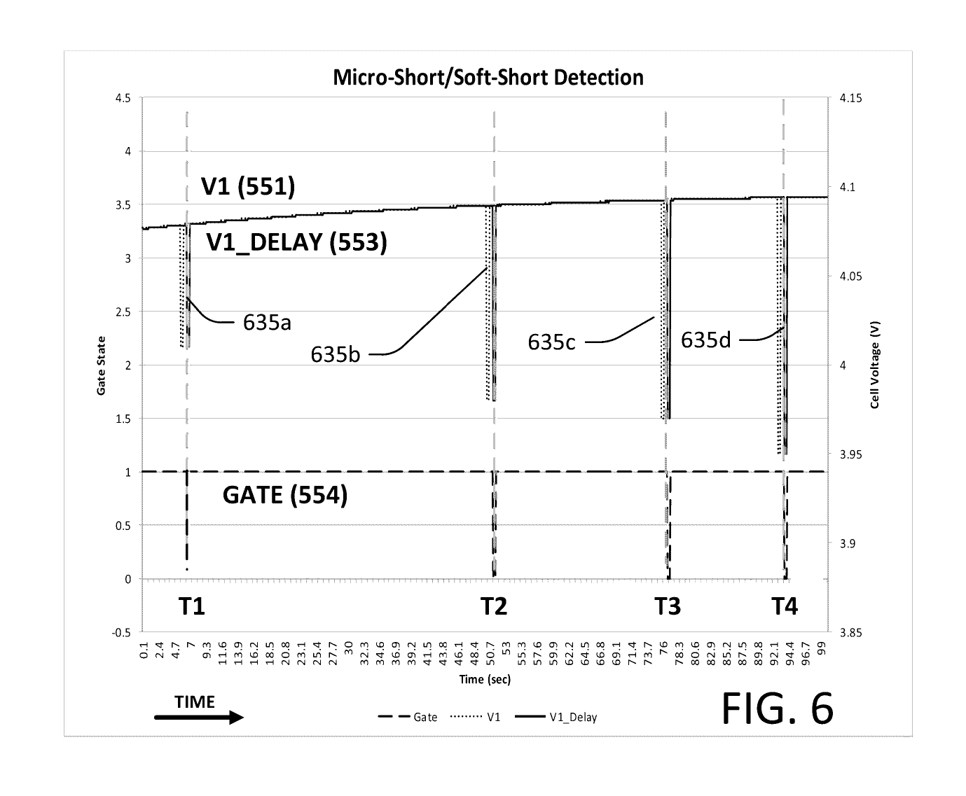

FIG. 6 is a timing diagram illustrating detection of micro-shorts by a detector device in one embodiment. With reference to FIG. 5, the diagram illustrates signals corresponding to first input 551a of comparator 555 (V1), a delayed signal as second input 553 to comparator 555 (V1_Delay), and output 554 of comparator 555 (“Gate”), which is the output of detector device 550 (“Gate signal”). At time T1, first micro-short 635a occurs, and is indicated by the negative spike of both V1 and V1_Delay. Due to the time delay between these signals, the negative spikes occur at different intervals, causing comparator 555 to output a “high” pulse for the duration of this time difference. At times T2, T3 and T4, further micro-shorts 635b-d occur, causing the Gate signal 554 to output additional corresponding pulses. Each of the pulses at times T1-T4 may be detected by control system 520 to indicate transient electrical short circuits, such as micro-shorts, exhibited by battery cell 590. In further embodiments, detector device 550 can be configured (e.g., incorporating additional circuitry) to lengthen the period of the pulse, thereby enabling easier or more reliable detection by control system 520.

FIG. 7 is a block diagram of battery system 700 implementing plurality of detectors 750a-d in a further embodiment of the invention. Battery system 700 includes battery module 110, which can incorporate features of battery module 110 described above with reference to FIG. 1. Similarly, BMS 120 interfaces with battery module 110, and can be configured to monitor voltage and temperature as described above with reference to FIG. 1. In contrast to system 100 of FIG. 1, battery system 700 includes four detector devices 750a-d, each of which may incorporate features of devices 150, 350, 550 described above. Each device 750a-d is connected to corresponding battery cell 190a-d, respectively, and may be configured to receive a signal indicating the voltage at respective battery cell 190a-d. When devices 750a-d detect a transient electrical short circuit, such as a micro-short, fault at corresponding battery cell 190b-d, the transient electrical short circuit they indicate fault by outputting fault signals (e.g., a pulse or a state change) 191a-d to the corresponding “short circuit” input at BMS 120. Upon receiving the fault, BMS 120 can take appropriate action, as described above.

FIG. 8 is a block diagram of battery system 800 implementing detector 850 in a still further embodiment of the invention. Battery system 800 includes battery module 110, which can incorporate features of battery module 110 described above with reference to FIG. 1. Similarly, BMS 120 interfaces with battery module 110, and may be configured to monitor voltage and temperature as described above with reference to FIG. 1. In contrast to the system 100 of FIG. 1, battery system 800 includes detector 850, which can incorporate features of devices 150, 350, 550 described above. Device 850 is connected to each of battery cells 190a-b individually via corresponding voltage channels V1-V4, and receives a signal from each voltage channel V1-V4 indicating the voltage at respective battery cell 190a-d. In order to monitor each of battery cells 190a-d for micro-shorts, detector 850 can include multiple circuits corresponding to one or both of detector devices 350, 550 described above with reference to FIGS. 3 and 5.

When detector device 850 detects a transient electrical short circuit fault, such as a micro-short, one or more of battery cells 190b-d, device 850 indicates the fault by outputting a fault signal (e.g., a pulse or a state change) to the “short circuit” input at BMS 120. In order to identify the given battery cell exhibiting the short, device 850 outputs a signal to BMS 120 (e.g., via the “short circuit” input or another input) that identifies the given battery cell. Upon receiving the fault, BMS 120 can take appropriate action as described above.

FIG. 9 is a block diagram of another embodiment of the invention. As shown therein, battery system 900 includes detector device 950. Detector device 950 can be implemented in battery system 100 described above with reference to FIG. 1, corresponding to detector device 150, which is also described above. In particular, battery module 910 sends signal 951 to detector 950 indicating the voltage of battery cell 990 (or, alternatively, a plurality of battery cells or a battery module), which corresponds to battery cells 190a-d of FIG. 1. Device 950 also outputs a signal 954 to control system 920, corresponding to BMS 120 of FIG. 1.

Detector device 950 corresponds to detector device 950 of FIG. 3, and can incorporate features of device 350 as described above. For example, as shown, device 950 includes inverter circuit 952 (e.g., an operational amplifier in an inverter configuration). However, in place of a NAND gate, device 950 includes voltage comparator 955. Both inputs 949a-b of inverter circuit 952 and first input 951A of comparator 955 can receive the same or a comparable signal from battery module 910 corresponding to the voltage of battery cell 990. Inverter circuit 952 outputs a delayed version of this signal as second input 953 of comparator 955. During a charge or discharge of battery cell 990, absent the occurrence of a transient electrical short circuit, such as a micro-short, comparator 955 outputs a steady-state signal to control system 920. Conversely, in the event of a micro-short, first input 951a of comparator 955 receives the voltage signal indicating a negative spike corresponding to the micro-short, and second input 953 to comparator 955 is (from inverter circuit 952) a delayed version of the negative spike corresponding to the micro-short. The delay in the spike received at first input 951a and second input 953 of comparator 955 causes comparator 955 to output a pulse. This pulse may, in turn, be detected by control system 920, indicating the occurrence of a transient electrical short circuit, such as a micro-short.

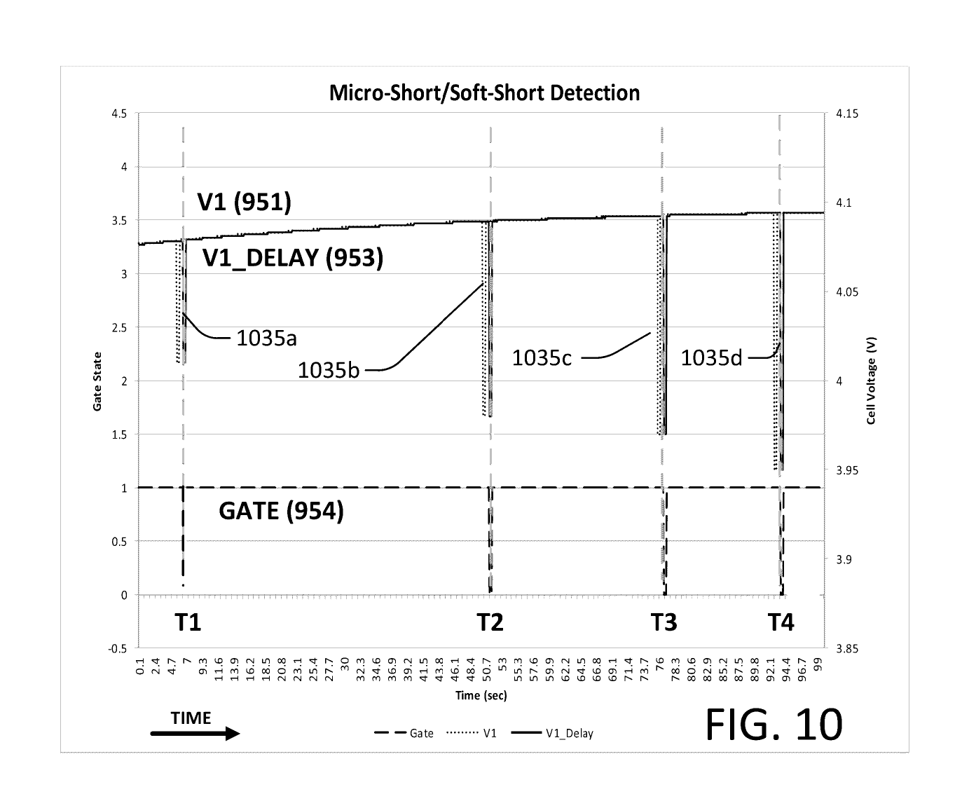

FIG. 10 is a timing diagram illustrating detection of micro-shorts by a detector device in one embodiment of the invention. With reference to FIG. 9, the diagram illustrates signals corresponding to first input 951a of comparator 955 (V1), a delayed signal as second input 953 to comparator 955 (V1_Delay), and output 954 of comparator 955 (“Gate”), which is the output of detector device 950 (“Gate signal”). At time T1, first micro-short 1035a occurs, and is indicated by the negative spike of both V1 and V1_Delay. Due to the time delay between these signals, the negative spikes occur at different intervals, causing comparator 955 to output a “high” pulse for the duration of this time difference. At times T2, T3 and T4, further micro-shorts 1035b-d occur, causing the Gate signal 954 to output additional corresponding pulses. Each of the pulses at times T1-T4 may be detected by control system 920 to indicate transient electrical short circuits, such as micro-shorts, exhibited by battery cell 990. In further embodiments, detector device 950 can be configured (e.g., incorporating additional circuitry) to lengthen the period of the pulse, thereby enabling easier or more reliable detection by control system 920.

While this invention has been particularly shown and described with references to example embodiments thereof, it will be understood by those skilled in the art that various changes in form and details may be made therein without departing from the scope of the invention encompassed by the appended claims.

What is claimed is:

1. A device for detecting a transient electrical short circuit in a battery cell, comprising:
a) a battery management system in electrical communication with terminals configured for connection with at least one battery, including an input voltage connection that is in electrical communication with a positive terminal of the battery, and including an output voltage connection that is in electrical communication with a negative terminal of the battery; and
b) a detection circuit, the detection circuit including
i) a comparator gate connected in parallel with electrical communication between the positive terminal of the battery and the input voltage connection, the comparator gate including a first input and a second input that are in electrical communication with the positive terminal of the battery, and an output in electrical communication with the battery management system;
ii) a time delay circuit between the positive terminal of the battery and the second input of the comparator gate, whereby communication of a transient short circuit in the battery is delayed by the time delay circuit, thereby causing the comparator gate to communicate, via the output, the transient short circuit to the battery management system over two distinct intervals that, in aggregate, are identified by the battery management system as a transient short circuit in the battery.

2. The device of claim 1, wherein the comparator gate is a NAND gate.

3. The device of claim 1, wherein the comparator gate is an AND gate.

4. The device of claim 1, wherein the comparator gate is a voltage comparator.

5. The device of claim 1, further including a fault parameter adjustment circuit providing electrical communication between the positive terminal of the battery and the detection circuit, whereby the amplitude of a change in voltage consequent to a transient electrical short circuit is controlled.

6. A method for detecting a transient electrical short circuit in a battery cell, comprising the steps of:
a) transmitting a first signal in parallel from a battery cell to a comparator gate and to a time delay circuit;
b) delaying the first signal at the time delay circuit to thereby form a second signal;
c) transmitting the second signal in parallel with the first signal to the comparator gate;
d) comparing the signals at the comparator gate, to generate a third signal, wherein a transient drop in voltage in the first and second signal is indicative of a transient short circuit in the battery cell is prolonged;
e) transmitting the third signal to the battery management system, whereby the prolonged transient drop in voltage is detected by the battery management system, thereby detecting the transient electrical short circuit in the battery.

7. The method of claim 6, wherein the transient short circuit is a micro-short circuit.
